(19) United States
(12) Patent Application Publication
(10) Pub. No.: US 2023/0420993 A1
(43) Pub. Date: Dec. 28, 2023

(54) ELECTRONIC DEVICE FOR WIRELESSLY RECEIVING POWER AND METHOD OF OPERATING THE SAME

(71) Applicants: Samsung Electronics Co., Ltd., Suwon-si (KR); Seoul National University R&DB Foundation, Seoul (KR)

(72) Inventors: Kyunghwan LEE, Suwon-si (KR); Jungik HA, Seoul (KR); Geonhong MIN, Suwon-si (KR); Junhyeong LEE, Seoul (KR)

(21) Appl. No.: 18/343,511

(22) Filed: Jun. 28, 2023

Related U.S. Application Data
(63) Continuation of application No. PCT/KR2023/008971, filed on Jun. 27, 2023.

(30) Foreign Application Priority Data
Jun. 28, 2022 (KR) 10-2022-0079177
Aug. 31, 2022 (KR) 10-2022-0110066

(51) Int. Cl. H02J 50/12; H02J 7/00

(52) U.S. Cl. CPC H02J 50/12; H02J 2207/20; H02J 7/0047; H02J 7/00712

(57) ABSTRACT

According to an embodiment, an electronic device for wirelessly receiving power may include: a power reception circuit including a coil, an impedance compensation circuit electrically connected to the power reception circuit, a rectifier circuit electrically connected to the impedance compensation circuit, a battery electrically connected to the rectifier circuit, and a control circuit electrically and/or operatively connected to the impedance compensation circuit, the rectifier circuit, and the battery. According to an embodiment, the control circuit may be configured to: rectify, by controlling the rectifier circuit, power received wirelessly from an external electronic device through the power reception circuit and the impedance compensation circuit into direct current (DC) power. According to an embodiment, the control circuit may be configured to identify at least one of a voltage or a current of the rectified DC power. According to an embodiment, the control circuit may be configured to determine a duty cycle of a control signal to control the impedance compensation circuit, based on the at least one of the voltage or the current. According to an embodiment, the control circuit may be configured to adjust a first voltage output by the impedance compensation circuit by controlling the impedance compensation circuit based on the duty cycle. According to an embodiment, impedance of the power reception circuit may be compensated based on the adjusted first voltage of the impedance compensation circuit.

### CROSS-REFERENCE TO RELATED APPLICATIONS

This application is a continuation of International Application No. PCT/KR2023/008971 designating the United States, filed on Jun. 27, 2023, in the Korean Intellectual Property Receiving Office and claiming priority to Korean Patent Application No. 10-2022-0079177, filed on Jun. 28, 2022, in the Korean Intellectual Property Office, and to Korean Patent Application No. 10-2022-0110066, filed on Aug. 31, 2022, in the Korean Intellectual Property Office, the disclosures of all of which are incorporated by reference herein in their entireties.

### BACKGROUND

### Field

The disclosure relates to an electronic device for wirelessly receiving power and a method of operating the same.

### Description of Related Art

Along with the development of wireless charging technology, a method of charging various electronic devices by supplying power to them with a single charging device is under study. This wireless charging technology relies on wireless power transmission and reception. For example, this is a system in which a battery is automatically chargeable by simply placing an electronic device on a charging pad without connecting the electronic device to a separate charging connector.

The wireless charging technology includes an electromagnetic induction scheme, a resonance scheme using resonance, or a radio frequency (RF)/microwave radiation scheme of converting electrical energy to microwaves and transferring the microwaves.

In a wireless charging-based power transmission method, power is transmitted between a first coil of a transmitter and a second coil of a receiver. As a magnetic field is generated, and current is induced or resonated according to a change in the magnetic field at the receiver, energy may be generated.

In a wireless power transmission technology using electromagnetic induction, power is transmitted using an electromagnetic field induced in a coil. A wireless power transmission device may generate an electromagnetic field by applying current to a transmission coil, and an induced electromotive force may be generated in a reception coil of a wireless power reception device, thereby wirelessly transmitting power.

### SUMMARY

According to an embodiment, an electronic device for wirelessly receiving power may include a power reception circuit including a coil, an impedance compensation circuit electrically connected to the power reception circuit, a rectifier circuit electrically connected to the impedance compensation circuit, a battery electrically connected to the rectifier circuit, and a control circuit electrically and/or operatively connected to the impedance compensation circuit, the rectifier circuit, and the battery. According to an embodiment, the control circuit may be configured to rectify, by controlling the rectifier circuit, power received wirelessly from an external electronic device through the power reception circuit and the impedance compensation circuit into direct current (DC) power. According to an embodiment, the control circuit may be configured to identify at least one of a voltage or a current of the rectified DC power. According to an embodiment, the control circuit may be configured to determine a duty cycle of a control signal to control the impedance compensation circuit, based on the at least one of the voltage or the current. According to an embodiment, the control circuit may be configured to adjust a first voltage output by the impedance compensation circuit by controlling the impedance compensation circuit based on the duty cycle. According to an embodiment, impedance of the power reception circuit may be compensated based on the adjusted first voltage of the impedance compensation circuit.

According to an embodiment, a method of operating an electronic device for wirelessly receiving power may include rectifying, by controlling a rectifier circuit included in the electronic device, power received wirelessly from an external electronic device into direct current (DC) power. According to an embodiment, the method of operating the electronic device may include identifying a voltage and a current of the rectified DC power. According to an embodiment, the method of operating the electronic device may include determining a duty cycle of a control signal to control an impedance compensation circuit included in the electronic device, based on the voltage and the current. According to an embodiment, the method of operating the electronic device may include adjusting a first voltage output by the impedance compensation circuit by controlling the impedance compensation circuit based on the duty cycle. According to an embodiment, impedance of a power reception circuit included in the electronic device may be compensated based on the adjusted first voltage of the impedance compensation circuit.

### BRIEF DESCRIPTION OF THE DRAWINGS

The above and other aspects, features and advantages of certain embodiments of the present disclosure will be more apparent from the following detailed description, taken in conjunction with the accompanying drawings, in which:

FIG. 1 is a block diagram illustrating an electronic device that wirelessly transmits power and an electronic device that wirelessly receives power according to various embodiments;

FIG. 2A is a block diagram illustrating a wireless power transmission device and a wireless power reception device according to an embodiment.

FIG. 2B is a block diagram illustrating a wireless power reception device according to an embodiment.

FIG. 2C is a block diagram illustrating a wireless power reception device according to an embodiment.

FIG. 2D is a block diagram illustrating a control circuit included in a wireless power reception device according to an embodiment.

FIGS. 3A and 3B are diagrams illustrating impedance compensation circuits according to an embodiment.

FIG. 4 is a flowchart illustrating a method of controlling power output from a rectifier circuit using an impedance compensation circuit in a wireless power reception device according to an embodiment.

FIG. 5 is a flowchart illustrating a method of outputting a first voltage by an impedance compensation circuit in a wireless power reception device according to an embodiment.

FIGS. 6A and 6B are graphs referred to for describing a method of outputting a first voltage by an impedance compensation circuit configured as a half bridge circuit in a wireless power reception device.

FIGS. 7A and 7B are graphs referred to for describing a method of outputting a first voltage by an impedance compensation circuit configured as a full bridge circuit in a wireless power reception device.

FIG. 8 is an equivalent circuit diagram illustrating a wireless power reception device based on impedance compensation of an impedance compensation circuit according to an embodiment.

FIG. 9 is a graph referred to for describing a method of adjusting an output voltage of a rectifier circuit by controlling compensation impedance in a wireless power reception device according to an embodiment.

FIG. 10 is a graph referred to for describing a method of adjusting an output voltage of a rectifier circuit by controlling a compensation impedance circuit in a wireless power reception device according to an embodiment.

FIG. 11 is a block diagram illustrating a wireless power reception device according to an embodiment.

FIG. 12 is a diagram illustrating a network environment according to various embodiments.

### DETAILED DESCRIPTION

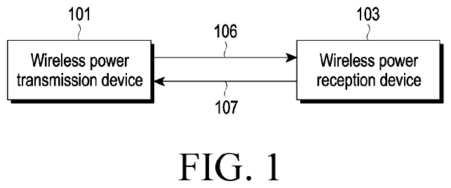

FIG. 1 is a block diagram illustrating an electronic device that wirelessly transmits power (hereinafter, referred to as a wireless power transmission device) and an electronic device that wirelessly receives power (hereinafter, referred to as a wireless power reception device) according to various embodiments.

Referring to FIG. 1, a wireless power transmission device 101 according to various embodiments may wirelessly transmit power 106 to a wireless power reception device 103. The wireless power transmission device 101 may receive information 107 from the wireless power reception device 103. In an example, the wireless power transmission device 101 may transmit the power 106 according to an induction scheme. When the wireless power transmission device 101 operates according to the induction scheme, the wireless power transmission device 101 may include at least one of, for example, a power source, a direct current-direct current (DC-DC) conversion circuit (e.g., a DC/DC converter), a direct current-alternating current (DC-AC) conversion circuit (e.g., an inverter), an amplifier circuit, an impedance matching circuit, at least one capacitor, at least one coil, or a communication modulation circuit. At least one capacitor together with at least one coil may form a resonant circuit. In an embodiment, the wireless power transmission device 101 may be implemented in a manner defined in the Qi standard of the wireless power consortium (WPC). The wireless power transmission device 101 may include a coil capable of generating an induced magnetic field when current flows according to the induction scheme. A process of generating an induced magnetic field in the wireless power transmission device 101 may be expressed as wireless transmission of the power 106 in the wireless power transmission device 101. In addition, an induced electromotive force (or current, voltage, and/or power) may be generated by a magnetic field generated around the coil of the wireless power reception device 103 according to the resonance scheme or the induction scheme in the coil of the wireless power reception device 103. A process of generating an induced electromotive force through the coil may be expressed as wireless power reception of the wireless power reception device 103.

The wireless power transmission device 101 according to various embodiments may communicate with the wireless power reception device 103. For example, the wireless power transmission device 101 may communicate with the wireless power reception device 103 in an in-band manner. The wireless power transmission device 101 may perform modulation on data to be transmitted, for example, according to a frequency shift keying (FSK) modulation scheme, and the wireless power reception device 103 may perform modulation using an amplitude shift keying (ASK) modulation scheme, thereby providing the information 107. The wireless power transmission device 101 may identify the information 107 provided by the wireless power reception device 103 based on the amplitude of a current and/or a voltage applied to a transmission coil. Although the wireless power reception device 103 is shown in FIG. 1 as directly transmitting the information 107 to the wireless power transmission device 101, this is only for ease of understanding, and those skilled in the art will understand that the wireless power reception device 103 controls on/off of at least one internal switch. An operation of performing modulation based on the ASK modulation scheme and/or the FSK modulation scheme may be understood as an operation of transmitting data (or a packet) according to an in-band communication scheme, and an operation of performing demodulation based on an ASK demodulation scheme and/or an FSK demodulation scheme may be understood as an operation of receiving data (or a packet) according to an in-band communication scheme.

In this disclosure, when it is said that the wireless power transmission device 101 or the wireless power reception device 103 performs a specific operation, this may imply that various hardware included in the wireless power transmission device 101 or the wireless power reception device 103, for example, a controller (e.g., a micro controlling unit (MCU), a field programmable gate array (FPGA), an application specific integrated circuit (ASIC), a microprocessor, or an application processor (AP)) performs the specific operation. When it is said that the wireless power transmission device 101 or the wireless power reception device 103 performs a specific operation, this may also imply that the controller included in the wireless power transmission device 101 or the wireless power reception device 103 controls other hardware to perform the specific operation. When it is said that the wireless power transmission device 101 or the wireless power reception device 103 performs a specific operation, this may also imply that as at least one instruction for performing the specific operation, stored in a storage circuit (e.g., memory) is executed, the controller or other hardware causes the specific operation to be performed.

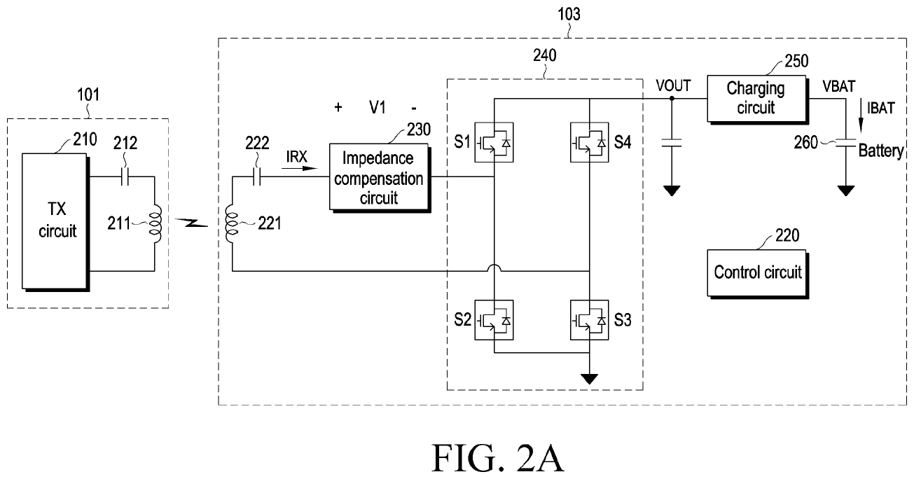

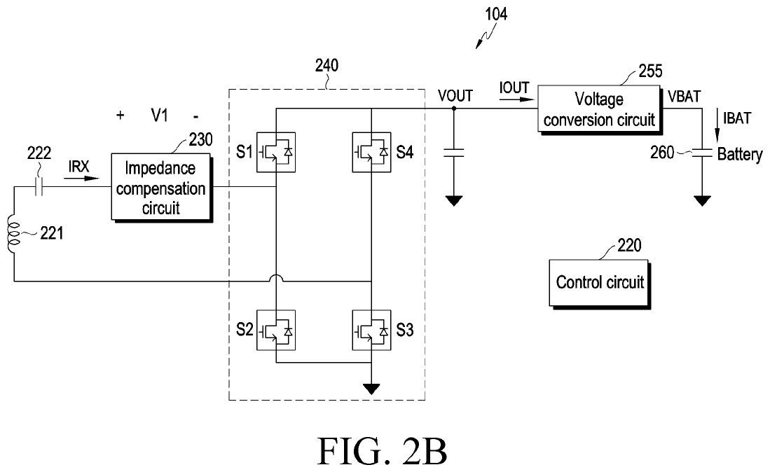

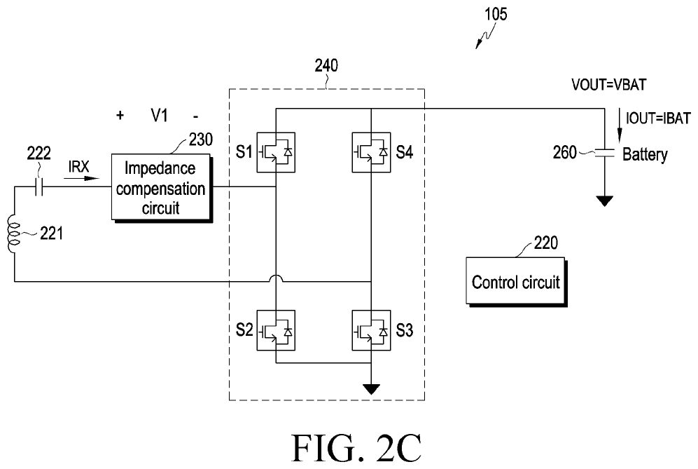

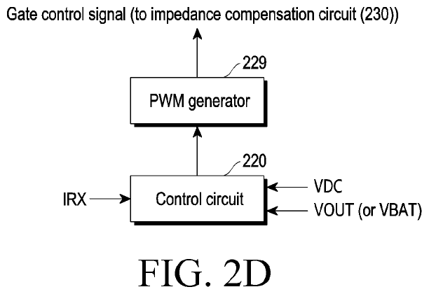

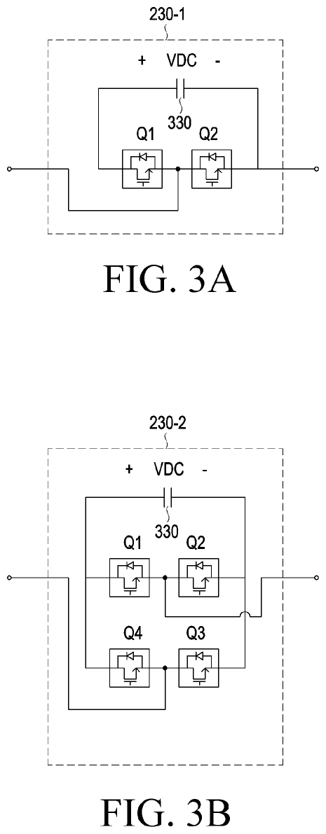

FIG. 2A is a block diagram illustrating a wireless power transmission device and a wireless power reception device according to an embodiment. FIGS. 3A and 3B are diagrams illustrating impedance compensation circuits according to an embodiment.

Referring to FIG. 2A, according to an embodiment, the wireless power transmission device 101 may include a transmission (TX) circuit 210, a first coil 211, and a capacitor 212.

According to an embodiment, the TX circuit 210 may provide power provided by a power source to the coil 211. According to an embodiment, the TX circuit 210 may include a power source (not shown), a DC/DC converter (not shown), and/or an inverter (not shown). For example, the power source may include at least one of an interface to connect to an external travel adapter (TA), a battery (not shown) of the wireless power transmission device 101, a charger (not shown), or a power management integrated circuit (PMIC) (not shown). According to an embodiment, the power provided by the power source may be provided to the DC/DC converter. Although the power source may provide, for example, DC power to the DC/DC converter, the type of the provided power is not limited. The DC/DC converter may convert the voltage of the received power and provide the converted voltage to the inverter. The DC/DC converter may change the voltage of input DC power and provide the DC power having the changed voltage (or a driving voltage VDD) to the inverter. It will be understood by those skilled in the art that although the DC/DC converter may perform, for example, buck conversion and/or boost conversion, the type of the DC/DC converter is not limited. The inverter may output AC power using the driving voltage provided by the DC/DC converter. For example, the inverter may include a plurality of switches that may form a full bridge circuit, and the number of switches or the type of the bridge circuit is not limited.

According to an embodiment, AC power generated by the TX circuit 210 may be applied to the first coil 211. The capacitor 212 may be a series compensation capacitor of the first coil 211. The first coil 211 may form a magnetic field based on the applied AC power. Part of the magnetic field (or magnetic flux) formed by the first coil 211 may be applied to a second coil 221 of the wireless power reception device 103. As the magnetic field applied to the second coil 221 of the wireless power reception device 103 changes over time, an induced electromotive force (e.g., current, voltage, or power) may be generated in the second coil 221 of the wireless power reception device 103.

According to an embodiment, the TX circuit 210 may identify information provided by the wireless power reception device 103 through the first coil 211. The TX circuit 210 may perform analog-to-digital conversion (ADC), for example, on a signal received through the first coil 211. The TX circuit 210 may decode a digital value obtained as a result of the ADC and identify the information provided by the wireless power reception device 103 according to a decoding result. Those skilled in the art will understand that the decoding scheme may conform to, but not limited to, for example, the Qi standard.

According to an embodiment, the wireless power reception device 103 may include at least one of a control circuit 220, the second coil 221, a capacitor 222, an impedance compensation circuit 230, a rectifier circuit 240, a charging circuit 250, and/or a battery 260.

According to an embodiment, an induced electromotive force (e.g., current, voltage, or power) may be generated in the second coil 221. According to the induced electromotive force generated in the second coil 221, a first current IRX may be conducted in the second coil 221. The first current IRX may be provided to the impedance compensation circuit 230 through the capacitor 222. The capacitor 222 may be connected in series to the second coil 221. For example, the capacitor 222 may be a series compensation capacitor.

According to an embodiment, the second coil 221 may have one end connected to the capacitor 222 and the other end connected to the rectifier circuit 240. According to an embodiment, the capacitor 222 may have one end connected to the reception coil 221 and the other end connected to one end of the impedance compensation circuit 230. According to an embodiment, the capacitor 222 may be connected in series between the second coil 221 and the impedance compensation circuit 230.

According to an embodiment, the leakage inductance of the wireless power reception device 103 may be equivalently modeled by a coupling ratio between the wireless power transmission device 101 and the wireless power reception device 103. For example, the leakage inductance (or inductance value) of the wireless power reception device 103 may be determined by a coupling ratio between the first coil 211 and the second coil 221.

According to an embodiment, the control circuit 220 may provide overall control to operations of the wireless power reception device 103. For example, the control circuit 220 may output a first voltage V1 through the impedance compensation circuit 230 to compensate or adjust the impedance of the wireless power reception device 103. When the first voltage V1 is output by the impedance compensation circuit 230, impedance Xa may be compensated by the first voltage V1 and the first current IRX applied to the impedance compensation circuit 230. The impedance Xa may be determined based on the first voltage V1 and the first current IRX according to Equation 1.

$$Xa = \frac{V 1}{IRX} \qquad [ Equation 1 ]$$

According to an embodiment, the control circuit 220 may compensate or adjust the impedance of the wireless power reception device 103 through the impedance compensation circuit 230. The control circuit 220 may control the magnitude of power (or a voltage) output from the rectifier circuit 240 based on the compensated or adjusted impedance. According to an embodiment, the control circuit 220 may control the magnitude of power (or a voltage) supplied to the battery 260 by compensating or adjusting the impedance of the wireless power reception device 103. For example, the impedance compensation circuit 230 may be an active impedance compensation circuit. For example, the control circuit 220 may apply a voltage (e.g., VDC) to the impedance compensation circuit 230.

Referring to FIGS. 3A and 3B, according to an embodiment, an impedance compensation circuit 230-1 or 230-2 illustrated in FIG. 3A or 3B may be applied as the impedance compensation circuit 230 of FIGS. 2A, 3B and 2C. According to an embodiment, each of the impedance compensation circuits 230-1 and 230-2 may include a plurality of switches. Each of the plurality of switches may be implemented as a metal oxide semiconductor field effect transistor (MOSFET). According to an embodiment, referring to FIG. 3A, the plurality of switches may be configured as a half bridge circuit. According to an embodiment, referring to FIG. 3B, the plurality of switches may be configured as a full bridge circuit. The numbers or types of switches illustrated in FIGS. 3A and 3B are merely exemplary, to which embodiments of the disclosure may not be limited.

Referring to FIG. 3A, according to an embodiment, a control circuit (the control circuit 220 of FIG. 2) may control a plurality of switches Q1 and Q2 so that the impedance compensation circuit 230-1 operates as a half bridge circuit. The control circuit 220 may apply a voltage VDC having a specified magnitude to a capacitor 330 included in the impedance compensation circuit 230-1. The plurality of switches Q1 and Q2 operating as a half bridge circuit may perform a rectification operation on the voltage VDC having the specified magnitude. According to the rectification operation, the impedance compensation circuit 230-1 may output the first voltage V1. For example, the control circuit 220 may close the first switch Q1 and open the second switch Q2 during a first period. Further, the control circuit 220 may open the first switch Q1 and close the second switch Q2 during a second period after the first period. The control circuit 220 may operate the impedance compensation circuit 230-1 as a half bridge circuit by repeating the above operation for the plurality of switches Q1 and Q2. The control circuit 220 may control a switching timing between the first period and the second period. Further, the control circuit 220 may control the durations of the first period and the second period. To this end, the control circuit 220 may apply a control signal to a gate of each of the first switch Q1 and the second switch Q2.

Referring to FIG. 3B, according to an embodiment, a control circuit (the control circuit 220 of FIG. 2) may control a plurality of switches Q1, Q2, Q3, and Q4 so that the impedance compensation circuit 230-2 operates as a full bridge circuit. The control circuit 220 may apply a voltage VDC having a specified magnitude to the capacitor 330 included in the impedance compensation circuit 230-2. The plurality of switches Q1, Q2, Q3, and Q4 operating as a full bridge circuit may perform a rectification operation on the voltage VDC having the specified magnitude. According to the rectification operation, the impedance compensation circuit 230-2 may output the first voltage V1. For example, the control circuit 220 may close the first switch Q1 and the third switch Q3 and open the second switch Q2 and the fourth switch Q4 during a first period. In addition, the control circuit 220 may open the first switch Q1 and the third switch Q3 and close the second switch Q2 and the fourth switch Q4 during a second period after the first period. The control circuit 220 may operate the impedance compensation circuit 230 as a full bridge circuit by repeating the above operation for the plurality of switches Q1, Q2, Q3, and Q4. The control circuit 220 may control a switching timing between the first period and the second period. Further, the control circuit 220 may control the durations of the first period and the second period. To this end, the control circuit 220 may apply a control signal to a gate of each of the plurality of switches Q1, Q2, Q3, and Q4.

According to an embodiment, when the impedance compensation circuit 230 is configured as a full bridge circuit, the impedance compensation circuit 230 may compensate impedance in a wider range than when it is configured as a half bridge circuit. For example, when the impedance compensation circuit 230 is configured as a full bridge circuit, the impedance compensation circuit 230 may adjust a voltage (e.g., an output voltage VOUT output from the rectifier circuit 240 and/or a battery voltage VBAT supplied to the battery 260) in a wider range than when the impedance compensation circuit 230 is configured as a half bridge circuit.

According to an embodiment, the rectifier circuit 240 may include a plurality of switches S1, S2, S3, and S4 that may be included in a full bridge circuit or a voltage doubler circuit. The plurality of switches S1, S2, S3, and S4 may be configured as a full bridge circuit. One end of the impedance compensation circuit 230 may be connected to a connection point between the switches S1 and S2, and the other end of the second coil 221 may be connected to a connection point between the switches S3 and S4. For example, one end of the first switch S1 and one end of the fourth switch S4 may be connected to the charging circuit 250, one end of the second switch S2 may be connected to the other end of the first switch S1, and one end of the third switch S3 may be connected to the other end of the fourth switch S4. The other end of the second switch S2 and the other end of the third switch S3 may be connected to a ground. The other end of the first switch S1 and the one end of the second switch S2 may be connected to the one end of the impedance compensation circuit 230, and the one end of the third switch S3 and the other end of the fourth switch S4 may be connected to the other end of the second coil 221. The rectifier circuit 240 may convert AC power received through the second coil 221 into DC power. The control circuit 220 may control on/off states of the plurality of switches S1, S2, S3, and S4 so that the AC power is converted into the DC power. The rectifier circuit 240 may rectify a power signal received from the second coil 221 and supply the rectified power signal to the charging circuit 250.

According to an embodiment, the charging circuit 250 may supply power to the battery 260. The control circuit 220 may output the first voltage V1 through the impedance compensation circuit 230 to supply power having a specified voltage to the battery 260. Depending on implementation, the charging circuit 250 may further include a voltage conversion circuit (e.g., a switched capacitor (SC) converter) that converts the voltage of power output from the rectifier circuit 240.

According to an embodiment, the wireless power reception device 103 may not include a regulator (e.g., a low dropout (LDO) regulator). For example, the rectifier circuit 240 may not include a regulator (e.g., an LDO regulator). The charging circuit 250 may not include a regulator (e.g., an LDO regulator). The charging circuit 250 may not perform a regulation function through control of a duty cycle of the impedance compensation circuit 230. The control circuit 220 may control the voltage of power supplied to the charging circuit 250, using the impedance compensation circuit 230. Since the wireless power reception device 103 according to an embodiment is capable of controlling the voltage of the power supplied to the charging circuit 250 through the impedance compensation circuit 230, an additional regulator may not be required to convert the power supplied to the charging circuit 250. Therefore, the wireless power reception device 103 according to an embodiment of the disclosure may increase the power density of a wireless charging system by eliminating the regulator. In addition, circuits may be miniaturized in the wireless power reception device 103 according to an embodiment of the disclosure by eliminating the regulator (e.g., the LDO regulator).

Depending on implementation, the wireless power reception device 103 may include a regulator (e.g., an LDO regulator). However, the regulator (e.g., the LDO regulator) may not be an essential component in the wireless power reception device 103 according to an embodiment of the disclosure, unlike a conventional wireless power reception device.

FIG. 2B is a block diagram illustrating a wireless power reception device according to an embodiment.

Referring to FIG. 2B, according to an embodiment, a wireless power reception device 104 may include a voltage conversion circuit 255 instead of the charging circuit 250, compared to the wireless power reception device 103 of FIG. 2A.

According to an embodiment, the wireless power reception device 104 may supply power output from the rectifier circuit 240 to the voltage conversion circuit 255. The voltage conversion circuit 255 may be implemented as an SC (switched capacitor) converter (or transformer). For example, the voltage conversion circuit 255 may change a voltage output from the rectifier circuit 240 by N times or 1/N times (e.g., N is a natural number equal to or greater than 2) and supply the changed voltage to the battery 260. Since the voltage conversion circuit 255 may control the power (or voltage) output from the rectifier circuit 240 through the impedance compensation circuit 230, the voltage conversion circuit 255 may not include a separate regulator (e.g., an LDO regulator).

Accordingly, since the wireless power reception device 104 according to an embodiment of the disclosure does not need to include a separate regulator (e.g., an LDO regulator) in the voltage conversion circuit 255, the power density of a wireless charging system may be increased. In addition, the voltage conversion circuit 255 may be miniaturized in the wireless power reception device 104 according to an embodiment of the disclosure.

FIG. 2C is a block diagram illustrating a wireless power reception device according to an embodiment.

Referring to FIG. 2C, according to an embodiment, a wireless power reception device 105 may not include the charging circuit 250, compared to the wireless power reception device 103 of FIG. 2A.

According to an embodiment, the wireless power reception device 105 may supply power output from the rectifier circuit 240 to the battery 260. Since the wireless power reception device 105 is capable of controlling the power output from the rectifier circuit 240 through the impedance compensation circuit 230, the wireless power reception device 105 may not include a separate charging circuit (e.g., the charging circuit 250 of FIG. 2A). For example, the output voltage VOUT of the rectifier circuit 240 may be equal to the battery voltage VBAT applied to the battery 260 in the wireless power reception device 105. Further, an output current IOUT of the rectifier circuit 240 may be equal to a battery current IBAT applied to the battery 260 in the wireless power reception device 105.

According to an embodiment, the wireless power reception device 105 may not include a regulator (e.g., an LDO regulator).

Therefore, the wireless power reception device 105 according to an embodiment of the disclosure may increase the power density of a wireless charging system by removing the regulator and the charging circuit. In addition, the wireless power reception device 105 according to an embodiment of the disclosure may be miniaturized by removing the regulator and the charging circuit.

FIG. 2D is a block diagram illustrating a control circuit included in a wireless power reception device according to an embodiment.

Referring to FIG. 2D, according to an embodiment, the control circuit 220 may identify the output voltage VOUT of the rectifier circuit 240 and/or the battery voltage VBAT supplied to the battery 260, while wirelessly receiving power from the wireless power transmission device 101.

According to an embodiment, the control circuit 220 may identify whether to adjust the output voltage VOUT and/or the battery voltage VBAT. When identifying that the output voltage VOUT and/or the battery voltage VBAT is to be adjusted, the control circuit 220 may identify the voltage VDC applied to the capacitor 330 of the impedance compensation circuit 230. The control circuit 220 may determine whether to adjust the magnitude of the voltage VDC applied to the capacitor 330 of the impedance compensation circuit 230. For example, the control circuit 220 may increase/decrease or maintain the magnitude of the voltage VDC applied to the capacitor 330 of the impedance compensation circuit 230 according to the determination.

According to an embodiment, when identifying that the output voltage VOUT and/or the battery voltage VBAT is to be adjusted, the control circuit 220 may identify the first current IRX conducted in the impedance compensation circuit 230. For example, the control circuit 220 may identify the first current IRX based on currents measured across the capacitor 222. Further, the control circuit 220 may identify the phase of the first current IRX. For example, the control circuit 220 may identify the phase of the first current IRX through a phase locked loop (PLL). For example, the PLL may be included in the control circuit 220 or implemented as separate hardware.

According to an embodiment, the control circuit 220 may determine the phase and/or duty cycle of the first voltage V1 to be output from the impedance compensation circuit 230 based on the phase of the first current IRX. For example, the control circuit 220 may control the switching timings of the plurality of switches included in the impedance compensation circuit 230 to adjust the phase and/or duty cycle of the first voltage V1. For example, the control circuit 220 may adjust the phase and/or duty cycle of the first voltage V1 so that the phase difference between the first voltage V1 and the first current IRX becomes 90 degrees or −90 degrees. To this end, the control circuit 220 may output a control signal to a pulse width modulation (PWM) generator 229. The PWM generator 229 may output a gate control signal to the plurality of switches included in the impedance compensation circuit 230 according to the control signal. Depending on implementation, the operation performed by the PWM generator 229 may be performed by the control circuit 220. That is, the control circuit 220 may directly output the gate control signal to the plurality of switches (e.g., the switches Q1 and Q2 of FIG. 3A or the switches Q1, Q2, Q3, and Q4 of FIG. 3B) included in the impedance compensation circuit 230 without the separate PWM generator 229.

According to an embodiment, when the first voltage V1 is output by the impedance compensation circuit 230, the impedance of the wireless power reception device 103 (e.g., a power reception circuit including the second coil 221 and the capacitor 222) may be compensated. For example, equivalent compensation impedance may be generated based on the first voltage V1 output from the impedance compensation circuit 230, and an impedance value of the wireless power reception device 103 may be changed by the generated compensation impedance. The control circuit 220 may adjust the output voltage VOUT output from the rectifier circuit 240 and/or the battery voltage VBAT supplied to the battery 260 to a constant level through impedance compensation of the wireless power reception device 103.

At least some of the following operations of the wireless power reception device 103 may be performed by the control circuit 220. However, for convenience of description, the corresponding operations will be described as being performed by the wireless power reception device 103.

The following operations may be performed by the wireless power reception devices 104 and 105 described with reference to FIGS. 2B and 2C. However, for convenience of description, the following operations will be described as being performed by the wireless power reception device 103.

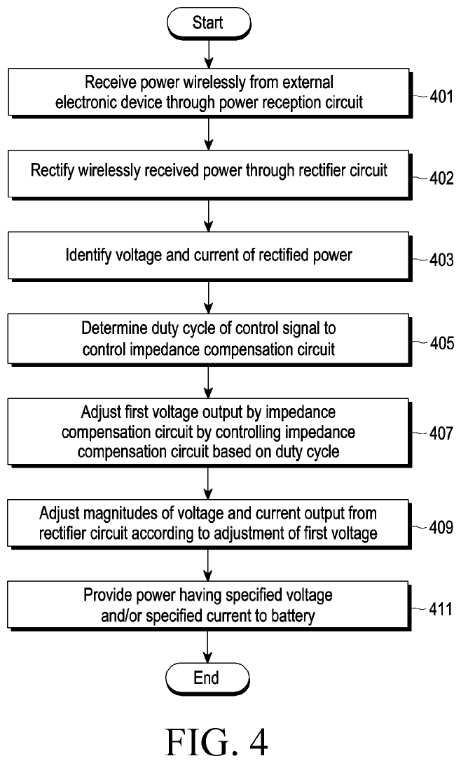

FIG. 4 is a flowchart illustrating a method of controlling power output from a rectifier circuit, using an impedance compensation circuit in a wireless power reception device according to an embodiment.

Referring to FIG. 4, according to an embodiment, the wireless power reception device 103 may wirelessly receive power from the external wireless power transmission device 101 through the power reception circuit including the second coil 221 in operation 401.

According to an embodiment, the wireless power reception device 103 may rectify the wirelessly received power into DC power through the rectifier circuit 240 in operation 402. For example, the wireless power reception device 103 may control the rectifier circuit 240 to rectify AC power provided through the power reception circuit (e.g., the second coil 221 and the capacitor 222) and the impedance compensation circuit 230 into DC power.

According to an embodiment, the wireless power reception device 103 may identify the voltage VOUT and current IOUT of the rectified power (e.g., the rectified DC power) in operation 403. For example, the wireless power reception device 103 may identify the magnitude of the voltage VOUT and/or current IOUT of the rectified power (e.g., the rectified DC power). According to an embodiment, the wireless power reception device 103 may identify the battery voltage VBAT and/or battery current IBAT applied to the battery 260. For example, the wireless power reception device 103 may identify the magnitude of the battery voltage VBAT and the magnitude of the battery current IBAT.

According to an embodiment, the wireless power reception device 103 may determine the duty cycle of a control signal to control the impedance compensation circuit 230 based on the voltage and/or current of the rectified power in operation 405. According to an embodiment, the wireless power reception device 103 may determine the duty cycle of the control signal to control the impedance compensation circuit 230, based on the voltage and/or current of the power applied to the battery 260.

According to an embodiment, the wireless power reception device 103 may adjust the first voltage V1 output from the impedance compensation circuit 230 by controlling the impedance compensation circuit 230 based on the duty cycle in operation 407. The wireless power reception device 103 may adjust at least one of the magnitude of the first voltage V1 output from the impedance compensation circuit 230 or a duty cycle. For example, the wireless power reception device 103 may adjust at least one of the magnitude of the first voltage V1 or the duty cycle based on the magnitude of the voltage and/or current of the rectified power (or the magnitude of the voltage and/or current supplied to the battery 260).

According to an embodiment, the wireless power reception device 103 may adjust the magnitude of a voltage and/or current output from the rectifier circuit 240 according to the adjustment of the first voltage V1 output from the impedance compensation circuit 230 in operation 409.

The impedance of the power reception circuit (e.g., the second coil 221 and the capacitor 222) may be changed or adjusted according to the adjustment of the first voltage V1. The wireless power reception device 103 may compensate the impedance of the power reception circuit according to the adjustment of the first voltage V1. In addition, depending on implementation, the wireless power reception device 103 may adjust the first voltage V1 output from the impedance compensation circuit 230 to compensate the impedance of the rectifier circuit 240. Accordingly, an impedance value of the wireless power reception device 103 may be changed based on the adjustment of the first voltage V1 output from the impedance compensation circuit 230.

According to an embodiment, the wireless power reception device 103 may provide power having a specified voltage and/or a specified current to the battery 260 in operation 411. For example, the wireless power reception device 103 may adjust power (e.g., voltage and/or current) output from the rectifier circuit 240 to a constant level through impedance compensation of the wireless power reception device 103. The wireless power reception device 103 may supply power having a specified voltage and/or a specified current to the battery 260 by adjusting the power output from the rectifier circuit 240.

According to an embodiment, in the case where the wireless power reception device 103 and the wireless power transmission device 101 are displaced in their arrangement (e.g., misaligned), when the wireless power reception device 103 wirelessly receives power from the wireless power transmission device 101, the transmitted power may be reduced. In this case, the wireless power reception device 103 may keep power having a specified voltage supplied to the battery 260, using the impedance compensation circuit 230, even if the wireless power reception device 103 does not request the wireless power transmission device 101 to transmit higher power. According to an embodiment of the disclosure, the wireless power reception device 103 may reduce dependence on the wireless power transmission device 101, using the impedance compensation circuit 230.

According to an embodiment, when the wireless power reception device 103 wirelessly receives power from the wireless power transmission device 101, the battery 260 of the wireless power reception device 103 may be fully charged. The wireless power reception device 103 may then stop the power transmission to the battery 260. However, even when the battery 260 of the wireless power reception device 103 is fully charged, the wireless power transmission device 101 may continue to transmit power to the wireless power reception device 103. In spite of the continuous power transmission of the wireless power transmission device 101, the wireless power reception device 103 may compensate impedance by adjusting the first voltage V1 output from the impedance compensation circuit 230, so that power is not supplied to the battery 260.

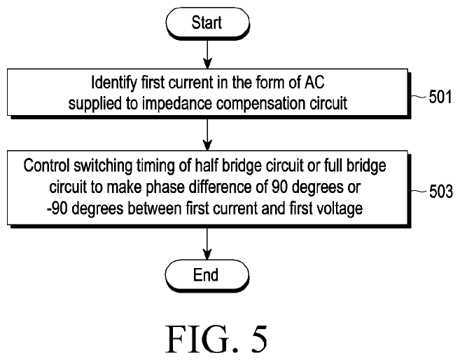

FIG. 5 is a flowchart illustrating a method of outputting a first voltage by an impedance compensation circuit in a wireless power reception device according to an embodiment.

Referring to FIG. 5, according to an embodiment, the wireless power reception device 103 may identify the first current IRX in the form of an AC supplied to the impedance compensation circuit 230 in operation 501. For example, the wireless power reception device 103 may identify the phase of the first current IRX by analyzing a current across the capacitor 222.

According to an embodiment, the wireless power reception device 103 may control the switching timing of the half bridge circuit or the full bridge circuit included in the impedance compensation circuit 230 so that the phase difference between the first current IRX and the first voltage V1 output from the impedance compensation circuit 230 is 90 degrees or −90 degrees in operation 503. When the phase difference is 90 degrees or −90 degrees, the magnitude of the first voltage V1 may be proportional to the magnitude of the voltage VDC applied to the capacitor 330 included in the impedance compensation circuit 230.

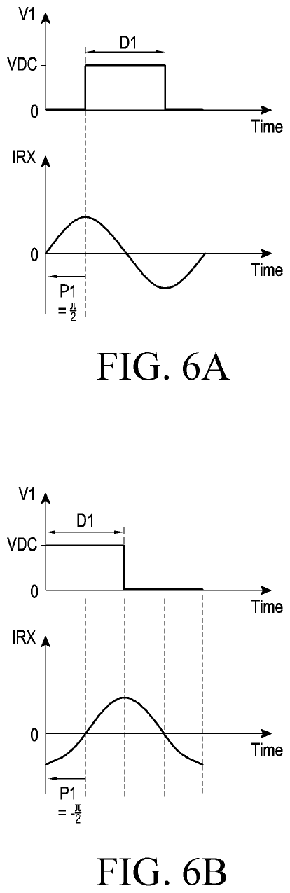

FIGS. 6A and 6B are graphs referred to for describing a method of outputting a first voltage by an impedance compensation circuit configured as a half bridge circuit in a wireless power reception device.

Referring to FIGS. 6A and 6B, the wireless power reception device 103 may identify the first current IRX conducted in the impedance compensation circuit 230. For example, the wireless power reception device 103 may determine at least one of the magnitude of the first voltage V1 output by the impedance compensation circuit 230 or a duty cycle based on the first current IRX conducted in the impedance compensation circuit 230. For example, in a state where the phase difference between the first current IRX and the first voltage V1 is 90 degrees or −90 degrees, and a constant voltage VDC is applied to the capacitor 330 included in the impedance compensation circuit 230, effective power consumed by the capacitor 330 may be zero. The wireless power reception device 103 may determine at least one of the magnitude of the first voltage V1 output by the impedance compensation circuit 230 or the duty cycle such that the effective power consumed by the capacitor 330 included in the impedance compensation circuit 230 becomes zero.

According to an embodiment, the wireless power reception device 103 may set a cycle of the first voltage V1 to be the same as a cycle of the first current IRX. The wireless power reception device 103 may determine switching timings of the plurality of switches (e.g., the switches Q1 and Q2 of FIG. 3A) included in the impedance compensation circuit 230 such that the phase difference between the first current IRX and the first voltage V1 is 90 degrees or −90 degrees. For example, the wireless power reception device 103 may apply a voltage with a first magnitude VDC to the capacitor 330 included in the impedance compensation circuit 230 so that the magnitude of the first voltage V1 becomes VDC. Since the impedance compensation circuit 230 is configured as a half bridge circuit, the first voltage V1 may have magnitudes of 0 and +VDC. Further, the wireless power reception device 103 may determine the duty cycle of the first voltage V1 such that the amplitude of the first voltage V1 becomes D1.

Referring to FIG. 6A, when the first current IRX is ahead of the first voltage V1 by 90 degrees

$$( or \frac{π}{2} ) ,$$

the phase difference between the first current IRX and the first voltage V1 may be 90 degrees

$$( or \frac{π}{2} ) .$$

When the phase difference is 90 degrees, the value of impedance compensated through the impedance compensation circuit 230 may have a positive value. For example, when the wireless power reception device 103 compensates impedance having a positive value, the wireless power reception device 103 may control the impedance compensation circuit 230 to output the first voltage V1 that lags behind the first current IRX by 90 degrees

$$( or \frac{π}{2} ) .$$

Referring to FIG. 6B, when the first current IRX lags behind the first voltage V1 by 90 degrees

$$( or \frac{π}{2} ) ,$$

the phase difference between the first current IRX and the first voltage V1 may be −90 degrees

$$( or - \frac{π}{2} ) .$$

When the phase difference is −90 degrees, the value of impedance compensated through the impedance compensation circuit 230 may have a negative value. For example, when the wireless power reception device 103 compensates impedance having a negative value, the wireless power reception device 103 may control the impedance compensation circuit 230 to output the first voltage V1 ahead of the first current IRX by 90 degrees

$$( or \frac{π}{2} ) .$$

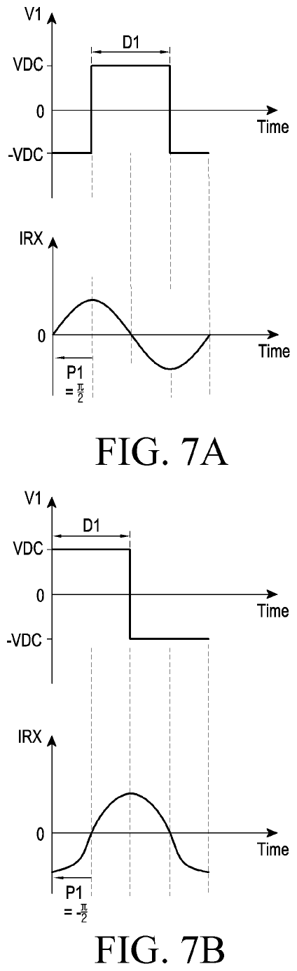

FIGS. 7A and 7B are graphs referred to for describing a method of outputting a first voltage by an impedance compensation circuit configured as a full bridge circuit in a wireless power reception device.

Referring to FIGS. 7A and 7B, the wireless power reception device 103 may identify the first current IRX conducted in the impedance compensation circuit 230. For example, the wireless power reception device 103 may determine at least one of the magnitude of the first voltage V1 output by the impedance compensation circuit 230 or a duty cycle based on the first current IRX conducted in the impedance compensation circuit 230. For example, in a state where the phase difference between the first current IRX and the first voltage V1 is 90 degrees or −90 degrees, and the constant voltage VDC is applied to the capacitor 330 included in the impedance compensation circuit 230, effective power consumed by the capacitor 330 may be zero. The wireless power reception device 103 may determine at least one of the magnitude of the first voltage V1 output by the impedance compensation circuit 230 or the duty cycle such that the effective power consumed by the capacitor 330 included in the impedance compensation circuit 230 becomes zero.

According to an embodiment, the wireless power reception device 103 may set the cycle of the first voltage V1 to be the same as the cycle of the first current IRX. The wireless power reception device 103 may determine switching timings of the plurality of switches (e.g., the switches Q1, Q2, Q3, and Q4 of FIG. 3B) included in the impedance compensation circuit 230 such that the phase difference between the first current IRX and the first voltage V1 is 90 degrees or −90 degrees. For example, the wireless power reception device 103 may apply a voltage with the first magnitude VDC to the capacitor 330 included in the impedance compensation circuit 230 so that the magnitude of the first voltage V1 becomes VDC. Since the impedance compensation circuit 230 is configured as a full bridge circuit, the first voltage V1 may have magnitudes of −VDC and +VDC. Further, the wireless power reception device 103 may determine the duty cycle of the first voltage V1 such that the amplitude of the first voltage V1 becomes D1.

Referring to FIG. 7A, when the first current IRX is ahead of the first voltage V1 by 90 degrees

$$( or \frac{π}{2} ) ,$$

the phase difference between the first current IRX and the first voltage V1 may be 90 degrees

$$( or \frac{π}{2} ) .$$

When the phase difference is 90 degrees, the value of impedance compensated through the impedance compensation circuit 230 may have a positive value. For example, when the wireless power reception device 103 compensates impedance having a positive value, the wireless power reception device 103 may control the impedance compensation circuit 230 to output the first voltage V1 that lags behind the first current IRX by 90 degrees

$$( or \frac{π}{2} ) .$$

Referring to FIG. 7B, when the first current IRX lags behind the first voltage V1 by 90 degrees

$$( or \frac{π}{2} ) ,$$

the phase difference between the first current IRX and the first voltage V1 may be −90 degrees

$$( or - \frac{π}{2} ) .$$

When the phase difference is −90 degrees, the value of impedance compensated through the impedance compensation circuit 230 may have a negative value. For example, when the wireless power reception device 103 compensates impedance having a negative value, the wireless power reception device 103 may control the impedance compensation circuit 230 to output the first voltage V1 ahead of the first current IRX by 90 degrees

$$( or \frac{π}{2} ) .$$

Referring to FIGS. 6A, 6B, 7A and 7B, according to an embodiment, the absolute value of impedance Xa compensated by the impedance compensation circuit 230 may be determined as in Equation 2. Herein, k is a proportional constant, VDC may be the magnitude of a voltage applied to the capacitor 330 included in the impedance compensation circuit 230, and IOUT may be the magnitude of a current output from the rectifier circuit 240.

$$\vert Xa \vert = \frac{k * VDC}{IOUT} \qquad [ Equation 2 ]$$

According to an embodiment, when the impedance compensation circuit 230 is configured as a half bridge circuit, the proportional constant k may be calculated as follows by first harmonic approximation (FHA) used in resonant converter analysis. The absolute value of Xa may be determined as in Equation 3.

$$\vert Xa \vert = \frac{2 * VDC / π}{IOUT} \qquad [ Equation 3 ]$$

According to an embodiment, when the impedance compensation circuit 230 is configured as a full bridge circuit, the proportional constant k may be calculated as follows by FHA used in resonant converter analysis. The absolute value of Xa may be determined as in Equation 4.

$$\vert Xa \vert = \frac{4 * VDC / π}{IOUT} \qquad [ Equation 4 ]$$

According to Equations 3 and 4, the magnitude of the impedance (|Xa| in Equation 4) compensated by the impedance compensation circuit 230-2 configured as a full bridge circuit may be twice the magnitude of the impedance (|Xa| in Equation 3) compensated by the impedance compensation circuit 230-1 configured as a half bridge circuit. For example, when the impedance compensation circuit 230 is configured as a full bridge circuit, a controllable compensation impedance range may be greater than when the impedance compensation circuit 230 is configured as a half bridge circuit. In addition, when the impedance compensation circuit 230 is configured as a full bridge circuit, a controllable range of the output voltage VOUT or the battery voltage VBAT may be greater than when the impedance compensation circuit 230 is configured as a half bridge circuit.

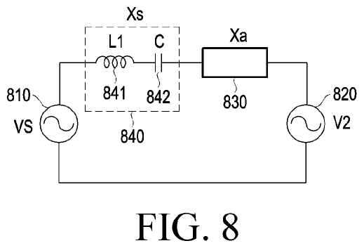

FIG. 8 is a diagram illustrating an equivalent circuit of a wireless power reception device based on impedance compensation of an impedance compensation circuit according to an embodiment.

Referring to FIG. 8, the equivalent circuit of the wireless power reception device 103 may include a first equivalent power source 810, a second equivalent power source 820, compensation impedance 830, and equivalent impedance 840.

According to an embodiment, the first equivalent power source 810 may be power obtained by equivalently modeling a voltage transmitted from the wireless power transmission device 101. The first equivalent power source 810 may be defined as VS.

According to an embodiment, the second equivalent power source 820 may be power obtained by equivalently modeling an AC voltage applied to the rectifier circuit 240. The second equivalent power source 820 may be defined as V2. For example, when the rectifier circuit 240 uses synchronous rectification, the second equivalent power source 820 and the first current IRX are in phase, and thus the second equivalent power source 820 may be modeled as resistance.

According to an embodiment, the compensation impedance 830 may be impedance obtained by equivalently modeling impedance which is compensated as the impedance compensation circuit 230 outputs the first voltage V1. The compensation impedance 830 may be defined as Xa.

According to an embodiment, the equivalent impedance 840 may be impedance obtained by equivalently modeling leakage inductance 841 and a DC compensation capacitor 842 of the wireless power reception device 103. The equivalent impedance 840 may be defined as Xs. The leakage inductance 841 included in the equivalent impedance 840 may be defined as L1, and the DC compensation capacitor 842 may be defined as C. Xs representing the equivalent impedance 840 may be determined according to Equation 5 below. Herein, ω may refer, for example, to a switching frequency of the wireless power transmission device 101. ωᵣ may be a variable representing a ratio between the resonant frequency of L1 and

$$C ( \frac{1}{√ L 1 C} )$$

and the switching frequency of the wireless power transmission device 101. For example, when a coupling ratio between the first coil 211 and the second coil 221 decreases, L1 and ωᵣ may increase.

$$Xs = \frac{ω L 1 - 1}{ω C} = \frac{{ω}_{r}^{2} - 1}{ω C} , {ω}_{r}^{2} = {ω}^{2} L 1 C \qquad [ Equation 5 ]$$

According to an embodiment, the output voltage VOUT of the rectifier circuit 240 may be inversely proportional to the value of |Xs+Xa|. When the value of Xs is zero (ωᵣ=1), the output voltage VOUT of the rectifier circuit 240 may increase as the value of |Xa| increases. When ωᵣ>1, the value of |Xs+Xa| may increase if the impedance compensation circuit 230 is controlled such that Xs>0 and Xa>0. When the value of |Xs+Xa| increases, the output voltage VOUT of the rectifier circuit 240 may decrease. When ωᵣ>1, if the impedance compensation circuit 230 is controlled such that Xs>0 and Xa<0, the value of |Xs+Xa| may decrease. When the value of |Xs+Xa| decreases, the output voltage VOUT of the rectifier circuit 240 may increase.

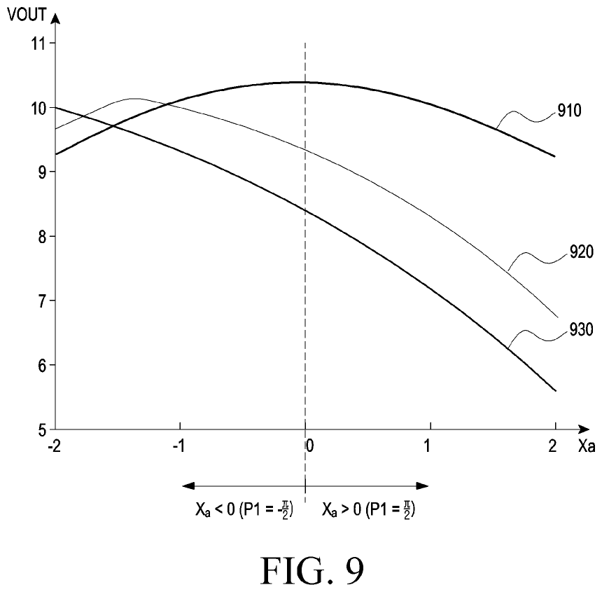

FIG. 9 is a graph referred to for describing a method of adjusting an output voltage of a rectifier circuit by controlling compensation impedance in a wireless power reception device according to various embodiments.

Referring to FIG. 9, according to an embodiment, when ωᵣ≥1, the wireless power reception device 103 may adjust the output voltage VOUT of the rectifier circuit 240 by controlling the compensation impedance Xa through the impedance compensation circuit 230.

According to an embodiment, a first graph 910 may represent a relationship between the compensation impedance Xa and the output voltage VOUT of the rectifier circuit 240, when ωᵣ=1. A second graph 920 may represent a relationship between the compensation impedance Xa and the output voltage VOUT of the rectifier circuit 240, when ωᵣ=1.3. A third graph 930 may represent a relationship between the compensation impedance Xa and the output voltage VOUT of the rectifier circuit 240, when ωᵣ=1.6.

According to an embodiment, the wireless power reception device 103 may increase the output voltage VOUT of the rectifier circuit 240 by increasing the value of |Xa| according to the first graph 910. Alternatively, the wireless power reception device 103 may decrease the output voltage VOUT of the rectifier circuit 240 by decreasing the value of |Xa| according to the first graph 910.

According to an embodiment, the wireless power reception device 103 may increase the output voltage VOUT of the rectifier circuit 240 by decreasing the value of Xa according to the second graph 920. The wireless power reception device 103 may decrease the output voltage VOUT of the rectifier circuit 240 by decreasing the value of Xa to “−1 or below” according to the second graph 920. The wireless power reception device 103 may decrease the output voltage VOUT of the rectifier circuit 240 by increasing the value of Xa according to the second graph 920.

According to an embodiment, the wireless power reception device 103 may increase the output voltage VOUT of the rectifier circuit 240 by decreasing the value of Xa according to the third graph 930. Alternatively, the wireless power reception device 103 may increase the output voltage VOUT of the rectifier circuit 240 by increasing the value of Xa according to the third graph 930.

According to an embodiment, when the compensation impedance Xa is zero, the wireless power reception device 103 may operate in the same manner as a conventional wireless power reception device that does not include the impedance compensation circuit 230. For example, as ωᵣ increases, the output voltage of the rectifier circuit may decrease in the conventional wireless power reception device. Even if ωᵣ is changed (or the coupling ratio between the first coil 211 and the second coil 221 is changed), the wireless power reception device 103 of the disclosure may keep the output voltage or output current of the rectifier circuit 240 constant (or at a specified level) by compensating the compensation impedance Xa.

According to the above-described method, the wireless power reception device 103 according to an embodiment of the disclosure may keep the output voltage and/or output current of the rectifier circuit 240 constant (or at a specified level) by compensating the compensation impedance Xa through the impedance compensation circuit 230.

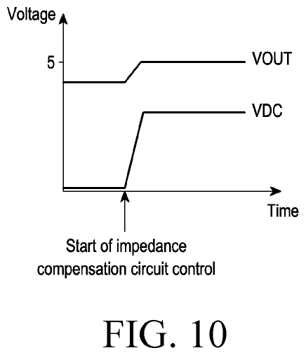

FIG. 10 is a graph referred to for describing a method of adjusting an output voltage of a rectifier circuit by controlling an impedance compensation circuit in a wireless power reception device according to an embodiment.

Referring to FIG. 10, according to an embodiment, the wireless power reception device 103 may compensate its impedance by outputting the first voltage V1 by the impedance compensation circuit 230. To this end, the wireless power reception device 103 may control the switching timing of the impedance compensation circuit 230. Further, the wireless power reception device 103 may apply a specified voltage VDC to the capacitor 330 included in the impedance compensation circuit 230.

According to an embodiment, when control of the impedance compensation circuit 230 starts, the wireless electronic receiver 103 may apply the specified voltage VDC to the capacitor 330 included in the impedance compensation circuit 230. The wireless electronic receiver 103 may equivalently generate the compensation impedance Xa based on the application of the specified voltage VDC to the capacitor 330 included in the impedance compensation circuit 230. Accordingly, the wireless electronic reception device 103 may adjust the output voltage VOUT (and/or the output current IOUT) of the rectifier circuit 240 to an intended level (e.g., 5V).

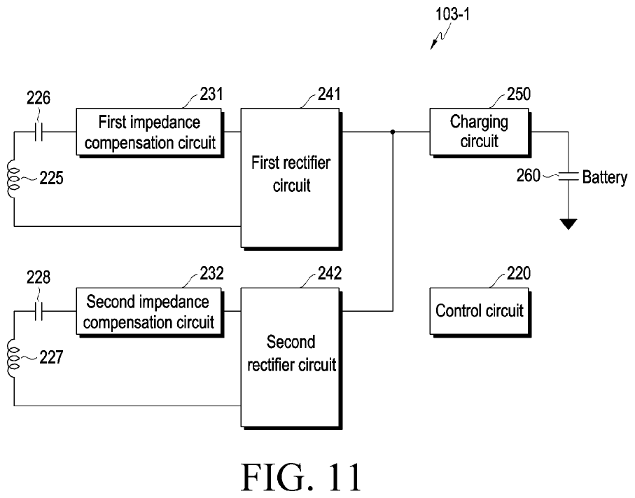

FIG. 11 is a block diagram illustrating a wireless power reception device according to an embodiment.

Referring to FIG. 11, a wireless power reception device 103-1 may include a plurality of coils 225 and 227 to wirelessly receive power, compared to the wireless power reception device 103 described with reference to FIG. 2A. Each of the plurality of coils 225 and 227 may be connected to the charging circuit 250 through a separate impedance compensation circuit 231 or 232 and a rectifier circuit 241 or 242.

According to an embodiment, when power is wirelessly received through one coil 225 of the plurality of coils 225 and 227, the control circuit 220 may compensate the impedance of a first power reception circuit (e.g., a circuit including the coil 225 and the capacitor 226) by controlling a first impedance compensation circuit 231. The control circuit 220 may adjust the output voltage and/or output current of a first rectifier circuit 241 through impedance compensation under the control of the first impedance compensation circuit 231. Therefore, the control circuit 220 may adjust the voltage and/or current supplied to the battery 260 to a constant or specified level.

According to an embodiment, when power is received wirelessly through the other coil 227 of the plurality of coils 225 and 227, the control circuit 220 may compensate the impedance of a second power reception circuit (e.g., a circuit including the coil 227 and the capacitor 228) by controlling a second impedance compensation circuit 232. The control circuit 220 may adjust the output voltage and/or output current of a second rectifier circuit 242 through impedance compensation under the control of the second impedance compensation circuit 232. Therefore, the control circuit 220 may adjust a voltage and/or current supplied to the battery 260 to a constant or specified level.

According to an embodiment, a method of controlling the first impedance compensation circuit 231 and the second impedance compensation circuit 232 may be implemented in the same manner as or a similar manner to the above-described operation of controlling the impedance compensation circuit 230.

While the wireless power reception device 103-1 is shown in FIG. 11 as including the charging circuit 250, this is merely an example, and the technical spirit of the disclosure may not be limited thereto. For example, depending on implementation, the wireless power reception device 103-1 may be without the charging circuit 250 or include the voltage conversion circuit 255 instead of the charging circuit 250, as illustrated in FIGS. 2B and 2C.

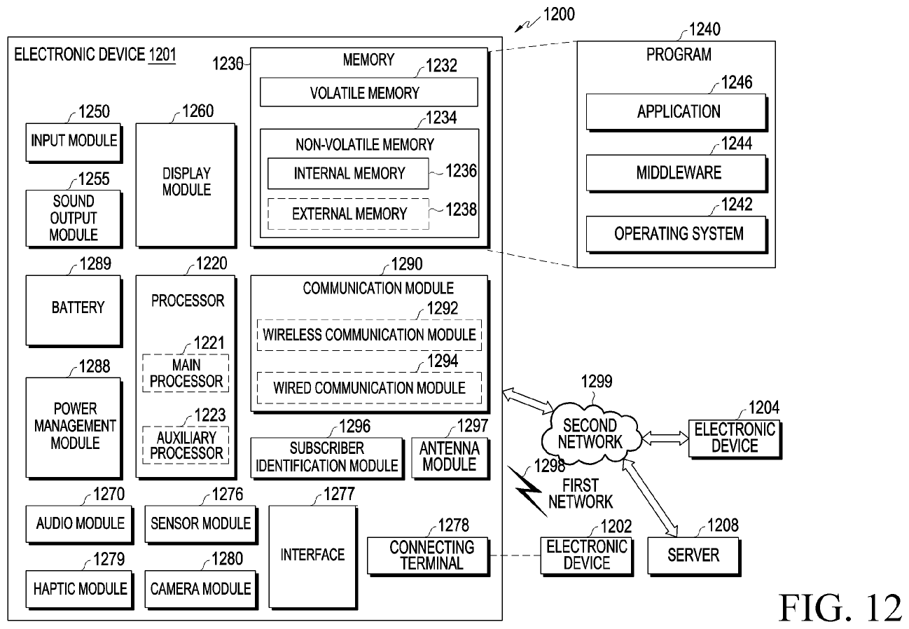

An electronic device 1201, 1202, or 1204 of FIG. 12 described below may be implemented identical or similar to the above-described electronic device 103, 103-1, 104, or 105.

FIG. 12 is a diagram illustrating a network environment according to various embodiments.

FIG. 12 is a block diagram illustrating an electronic device 1201 in a network environment 1200 according to various embodiments. Referring to FIG. 12, the electronic device 1201 in the network environment 1200 may communicate with an electronic device 1202 via a first network 1298 (e.g., a short-range wireless communication network), or at least one of an electronic device 1204 or a server 1208 via a second network 1299 (e.g., a long-range wireless communication network). According to an embodiment, the electronic device 1201 may communicate with the electronic device 1204 via the server 1208. According to an embodiment, the electronic device 1201 may include a processor 1220, memory 1230, an input module 1250, a sound output module 1255, a display module 1260, an audio module 1270, a sensor module 1276, an interface 1277, a connecting terminal 1278, a haptic module 1279, a camera module 1280, a power management module 1288, a battery 1289, a communication module 1290, a subscriber identification module (SIM) 1296, or an antenna module 1297. In various embodiments, at least one of the components (e.g., the connecting terminal 1278) may be omitted from the electronic device 1201, or one or more other components may be added in the electronic device 1201. In various embodiments, some of the components (e.g., the sensor module 1276, the camera module 1280, or the antenna module 1297) may be implemented as a single component (e.g., the display module 1260).

The processor 1220 may execute, for example, software (e.g., a program 1240) to control at least one other component (e.g., a hardware or software component) of the electronic device 1201 coupled with the processor 1220, and may perform various data processing or computation. According to an embodiment, as at least part of the data processing or computation, the processor 1220 may store a command or data received from another component (e.g., the sensor module 1276 or the communication module 1290) in volatile memory 1232, process the command or the data stored in the volatile memory 1232, and store resulting data in non-volatile memory 1234. According to an embodiment, the processor 1220 may include a main processor 1221 (e.g., a central processing unit (CPU) or an application processor (AP)), or an auxiliary processor 1223 (e.g., a graphics processing unit (GPU), a neural processing unit (NPU), an image signal processor (ISP), a sensor hub processor, or a communication processor (CP)) that is operable independently from, or in conjunction with, the main processor 1221. For example, when the electronic device 1201 includes the main processor 1221 and the auxiliary processor 1223, the auxiliary processor 1223 may be adapted to consume less power than the main processor 1221, or to be specific to a specified function. The auxiliary processor 1223 may be implemented as separate from, or as part of the main processor 1221.

The auxiliary processor 1223 may control at least some of functions or states related to at least one component (e.g., the display module 1260, the sensor module 1276, or the communication module 1290) among the components of the electronic device 1201, instead of the main processor 1221 while the main processor 1221 is in an inactive (e.g., sleep) state, or together with the main processor 1221 while the main processor 1221 is in an active state (e.g., executing an application). According to an embodiment, the auxiliary processor 1223 (e.g., an image signal processor or a communication processor) may be implemented as part of another component (e.g., the camera module 1280 or the communication module 1290) functionally related to the auxiliary processor 1223. According to an embodiment, the auxiliary processor 1223 (e.g., the neural processing unit) may include a hardware structure specified for artificial intelligence model processing. An artificial intelligence model may be generated by machine learning. Such learning may be performed, e.g., by the electronic device 1201 where the artificial intelligence is performed or via a separate server (e.g., the server 1208). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 1230 may store various data used by at least one component (e.g., the processor 1220 or the sensor module 1276) of the electronic device 1201. The various data may include, for example, software (e.g., the program 1240) and input data or output data for a command related thereto. The memory 1230 may include the volatile memory 1232 or the non-volatile memory 1234.

The program 1240 may be stored in the memory 1230 as software, and may include, for example, an operating system (OS) 1242, middleware 1244, or an application 1246.

The input module 1250 may receive a command or data to be used by another component (e.g., the processor 1220) of the electronic device 1201, from the outside (e.g., a user) of the electronic device 1201. The input module 1250 may include, for example, a microphone, a mouse, a keyboard, a key (e.g., a button), or a digital pen (e.g., a stylus pen).

The sound output module 1255 may output sound signals to the outside of the electronic device 1201. The sound output module 1255 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 1260 may visually provide information to the outside (e.g., a user) of the electronic device 1201. The display module 1260 may include, for example, a display, a hologram device, or a projector and control circuitry to control a corresponding one of the display, hologram device, and projector. According to an embodiment, the display module 1260 may include a touch sensor adapted to detect a touch, or a pressure sensor adapted to measure the intensity of force incurred by the touch.

The audio module 1270 may convert a sound into an electrical signal and vice versa. According to an embodiment, the audio module 1270 may obtain the sound via the input module 1250, or output the sound via the sound output module 1255 or a headphone of an external electronic device (e.g., an electronic device 1202) directly (e.g., wiredly) or wirelessly coupled with the electronic device 1201.

The sensor module 1276 may detect an operational state (e.g., power or temperature) of the electronic device 1201 or an environmental state (e.g., a state of a user) external to the electronic device 1201, and then generate an electrical signal or data value corresponding to the detected state. According to an embodiment, the sensor module 1276 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 1277 may support one or more specified protocols to be used for the electronic device 1201 to be coupled with the external electronic device (e.g., the electronic device 1202) directly (e.g., wiredly) or wirelessly. According to an embodiment, the interface 1277 may include, for example, a high definition multimedia interface (HDMI), a universal serial bus (USB) interface, a secure digital (SD) card interface, or an audio interface.

A connecting terminal 1278 may include a connector via which the electronic device 1201 may be physically connected with the external electronic device (e.g., the electronic device 1202). According to an embodiment, the connecting terminal 1278 may include, for example, a HDMI connector, a USB connector, a SD card connector, or an audio connector (e.g., a headphone connector).

The haptic module 1279 may convert an electrical signal into a mechanical stimulus (e.g., a vibration or a movement) or electrical stimulus which may be recognized by a user via his tactile sensation or kinesthetic sensation. According to an embodiment, the haptic module 1279 may include, for example, a motor, a piezoelectric element, or an electric stimulator.

The camera module 1280 may capture a still image or moving images. According to an embodiment, the camera module 1280 may include one or more lenses, image sensors, image signal processors, or flashes.

The power management module 1288 may manage power supplied to the electronic device 1201. According to an embodiment, the power management module 1288 may be implemented as at least part of, for example, a power management integrated circuit (PMIC).

The battery 1289 may supply power to at least one component of the electronic device 1201. According to an embodiment, the battery 1289 may include, for example, a primary cell which is not rechargeable, a secondary cell which is rechargeable, or a fuel cell.

The communication module 1290 may support establishing a direct (e.g., wired) communication channel or a wireless communication channel between the electronic device 1201 and the external electronic device (e.g., the electronic device 1202, the electronic device 1204, or the server 1208) and performing communication via the established communication channel. The communication module 1290 may include one or more communication processors that are operable independently from the processor 1220 (e.g., the application processor (AP)) and supports a direct (e.g., wired) communication or a wireless communication. According to an embodiment, the communication module 1290 may include a wireless communication module 1292 (e.g., a cellular communication module, a short-range wireless communication module, or a global navigation satellite system (GNSS) communication module) or a wired communication module 1294 (e.g., a local area network (LAN) communication module or a power line communication (PLC) module). A corresponding one of these communication modules may communicate with the external electronic device via the first network 1298 (e.g., a short-range communication network, such as Bluetooth™, wireless-fidelity (Wi-Fi) direct, or infrared data association (IrDA)) or the second network 1299 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 1292 may identify and authenticate the electronic device 1201 in a communication network, such as the first network 1298 or the second network 1299, using subscriber information (e.g., international mobile subscriber identity (IMSI)) stored in the subscriber identification module 1296.

The wireless communication module 1292 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 1292 may support a high-frequency band (e.g., the mmWave band) to achieve, e.g., a high data transmission rate. The wireless communication module 1292 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 1292 may support various requirements specified in the electronic device 1201, an external electronic device (e.g., the electronic device 1204), or a network system (e.g., the second network 1299). According to an embodiment, the wireless communication module 1292 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 1297 may transmit or receive a signal or power to or from the outside (e.g., the external electronic device) of the electronic device 1201. According to an embodiment, the antenna module 1297 may include an antenna including a radiating element composed of a conductive material or a conductive pattern formed in or on a substrate (e.g., a printed circuit board (PCB)). According to an embodiment, the antenna module 1297 may include a plurality of antennas (e.g., array antennas). In such a case, at least one antenna appropriate for a communication scheme used in the communication network, such as the first network 1298 or the second network 1299, may be selected, for example, by the communication module 1290 (e.g., the wireless communication module 1292) from the plurality of antennas. The signal or the power may then be transmitted or received between the communication module 1290 and the external electronic device via the selected at least one antenna. According to an embodiment, another component (e.g., a radio frequency integrated circuit (RFIC)) other than the radiating element may be additionally formed as part of the antenna module 1297.

According to various embodiments, the antenna module 1297 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 1201 and the external electronic device 1204 via the server 1208 coupled with the second network 1299. Each of the electronic devices 1202 or 1204 may be a device of a same type as, or a different type, from the electronic device 1201. According to an embodiment, all or some of operations to be executed at the electronic device 1201 may be executed at one or more of the external electronic devices 1202, 1204, or 1208. For example, if the electronic device 1201 should perform a function or a service automatically, or in response to a request from a user or another device, the electronic device 1201, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 1201. The electronic device 1201 may provide the outcome, with or without further processing of the outcome, as at least part of a reply to the request. To that end, a cloud computing, distributed computing, mobile edge computing (MEC), or client-server computing technology may be used, for example. The electronic device 1201 may provide ultra low-latency services using, e.g., distributed computing or mobile edge computing. In an embodiment, the external electronic device 1204 may include an internet-of-things (IoT) device. The server 1208 may be an intelligent server using machine learning and/or a neural network. According to an embodiment, the external electronic device 1204 or the server 1208 may be included in the second network 1299. The electronic device 1201 may be applied to intelligent services (e.g., smart home, smart city, smart car, or healthcare) based on 5G communication technology or IoT-related technology.

According to an embodiment, an electronic device for wirelessly receiving power may include: a power reception circuit including a coil, an impedance compensation circuit electrically connected to the power reception circuit, a rectifier circuit electrically connected to the impedance compensation circuit, a battery electrically connected to the rectifier circuit, and a control circuit electrically and/or operatively connected to the impedance compensation circuit, the rectifier circuit, and the battery. According to an example embodiment, the control circuit may be configured to: rectify, by controlling the rectifier circuit, power received wirelessly from an external electronic device through the power reception circuit and the impedance compensation circuit into direct current (DC) power. According to an embodiment, the control circuit may be configured to identify at least one of a voltage or a current of the rectified DC power. According to an embodiment, the control circuit may be configured to determine a duty cycle of a control signal to control the impedance compensation circuit, based on the at least one of the voltage or the current. According to an embodiment, the control circuit may be configured to adjust a first voltage output by the impedance compensation circuit by controlling the impedance compensation circuit based on the duty cycle. According to an embodiment, impedance of the power reception circuit may be compensated based on the adjusted first voltage of the impedance compensation circuit.

According to an embodiment, the control circuit may be configured to adjust a magnitude of the voltage and/or the current of the DC power output from the rectifier circuit by adjusting at least one of a magnitude of the first voltage or the duty cycle.

According to an embodiment, the control circuit may be configured to provide power having a specified voltage and a specified current to the battery by adjusting at least one of a magnitude of the first voltage or the duty cycle, while receiving the power wirelessly from the external electronic device.

According to an embodiment, the impedance compensation circuit may include a half bridge circuit or a full bridge circuit.

According to an embodiment, the control circuit may be configured to identify a first current in the form of an alternating current (AC) supplied from the power reception circuit to the impedance compensation circuit. According to an embodiment, the control circuit may be configured to control a switching timing of the half bridge circuit or the full bridge circuit to make a phase difference of 90 degrees or −90 degrees between the first current and the first voltage.

According to an embodiment, the control circuit may be configured to supply a voltage having a same magnitude as the first voltage to a capacitor included in the impedance compensation circuit.

According to an embodiment, the rectifier circuit may not include a low dropout (LDO) regulator.

According to an embodiment, the electronic device may further include a charging circuit supplying power output from the rectifier circuit to the battery. According to an embodiment, the charging circuit may not include a low dropout (LDO) regulator or does not perform a regulation function through control of the duty cycle.

According to an embodiment, the charging circuit may further include a switched capacitor (SC) converter converting a voltage of power output from the rectifier circuit.

According to an embodiment, the control circuit may be configured to directly supply power output from the rectifier circuit to the battery.

According to an embodiment, a method of operating an electronic device for wirelessly receiving power may include: rectifying, by controlling a rectifier circuit included in the electronic device, power received wirelessly from an external electronic device into direct current (DC) power. According to an embodiment, the method of operating the electronic device may include identifying a voltage and a current of the rectified DC power. According to an embodiment, the method of operating the electronic device may include determining a duty cycle of a control signal to control an impedance compensation circuit included in the electronic device, based on the voltage and the current. According to an embodiment, the method of operating the electronic device may include adjusting a first voltage output by the impedance compensation circuit by controlling the impedance compensation circuit based on the duty cycle. According to an embodiment, impedance of a power reception circuit included in the electronic device may be compensated based on the adjusted first voltage of the impedance compensation circuit.

According to an embodiment, the method of operating the electronic device may further include adjusting a magnitude of the voltage and/or the current of the DC power output from the rectifier circuit by adjusting at least one of a magnitude of the first voltage or the duty cycle.

According to an embodiment, the method of operating the electronic device may further include providing power having a specified voltage and a specified current to a battery by adjusting at least one of a magnitude of the first voltage or the duty cycle, while receiving the power wirelessly from the external electronic device.

According to an embodiment, the impedance compensation circuit may include a half bridge circuit or a full bridge circuit.

According to an embodiment, determining the at least one of the magnitude of the first voltage or the duty cycle may include identifying a first current in the form of an AC current supplied from the power reception circuit to the impedance compensation circuit. According to an embodiment, determining the at least one of the magnitude of the first voltage or the duty cycle may include controlling a switching timing of the half bridge circuit or the full bridge circuit to make a phase difference of 90 degrees or −90 degrees between the first current and the first voltage.

According to an embodiment, determining the at least one of the magnitude of the first voltage or the duty cycle may include supplying a voltage having a same magnitude as the first voltage to a capacitor included in the impedance compensation circuit.

According to an embodiment, the rectifier circuit may not include a low dropout (LDO) regulator.

According to an embodiment, the electronic device may further include a charging circuit supplying power output from the rectifier circuit to the battery. According to an embodiment, the charging circuit may not include a low dropout (LDO) regulator or may not perform a regulation function through control of the duty cycle.

According to an embodiment, the charging circuit may further include a switched capacitor (SC) converter converting a voltage of power output from the rectifier circuit.

According to an embodiment, the method of operating the electronic device may further include directly supplying power output from the rectifier circuit to the battery.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

While the disclosure has been illustrated and described with reference to various example embodiments, it will be understood that the various example embodiments are intended to be illustrative, not limiting. It will be further understood by those skilled in the art that various changes in form and detail may be made without departing from the true spirit and full scope of the disclosure, including the appended claims and their equivalents. It will also be understood that any of the embodiment(s) described herein may be used in conjunction with any other embodiment(s) described herein.

What is claimed is:

1. An electronic device for wirelessly receiving power, comprising:
a power reception circuit including a coil;
an impedance compensation circuit electrically connected to the power reception circuit;
a rectifier circuit electrically connected to the impedance compensation circuit;
a battery electrically connected to the rectifier circuit; and
a control circuit electrically and/or operatively connected to the impedance compensation circuit, the rectifier circuit, and the battery,
wherein the control circuit is configured to:
rectify, by controlling the rectifier circuit, power received wirelessly from an external electronic device through the power reception circuit and the impedance compensation circuit into direct current (DC) power,
identify at least one of a voltage or a current of the rectified DC power,
determine a duty cycle of a control signal to control the impedance compensation circuit, based on the at least one of the voltage or the current, and
adjust a first voltage output by the impedance compensation circuit, by controlling the impedance compensation circuit based on the duty cycle,
wherein impedance of the power reception circuit is compensated based on the adjusted first voltage of the impedance compensation circuit.

2. The electronic device of claim 1, wherein the control circuit is configured to adjust a magnitude of the voltage and/or the current of the DC power output from the rectifier circuit by adjusting at least one of a magnitude of the first voltage or the duty cycle.

3. The electronic device of claim 1, wherein the control circuit is configured to provide power having a specified voltage and a specified current to the battery by adjusting at least one of a magnitude of the first voltage or the duty cycle, while receiving the power wirelessly from the external electronic device.

4. The electronic device of claim 1, wherein the impedance compensation circuit includes a half bridge circuit or a full bridge circuit.

5. The electronic device of claim 4, wherein the control circuit is configured to:
identify a first current in the form of an alternating current (AC) supplied from the power reception circuit to the impedance compensation circuit, and
control a switching timing of the half bridge circuit or the full bridge circuit to make a phase difference of 90 degrees or −90 degrees between the first current and the first voltage.

6. The electronic device of claim 5, wherein the control circuit is configured to supply a voltage having a same magnitude as the first voltage to a capacitor included in the impedance compensation circuit.

7. The electronic device of claim 1, wherein the rectifier circuit does not include a low dropout (LDO) regulator.

8. The electronic device of claim 1, further comprising a charging circuit supplying power output from the rectifier circuit to the battery,
wherein the charging circuit does not include a low dropout (LDO) regulator or does not perform a regulation function through control of the duty cycle.

9. The electronic device of claim 8, wherein the charging circuit further includes a switched capacitor (SC) converter converting a voltage of power output from the rectifier circuit.

10. The electronic device of claim 1, wherein the control circuit is configured to directly supply power output from the rectifier circuit to the battery.

11. A method of operating an electronic device for wirelessly receiving power, the method comprising:
rectifying, by controlling a rectifier circuit included in the electronic device, power received wirelessly from an external electronic device into direct current (DC) power;
identifying a voltage and a current of the rectified DC power;
determining a duty cycle of a control signal to control an impedance compensation circuit included in the electronic device, based on the voltage and the current; and
adjusting a first voltage output by the impedance compensation circuit by controlling the impedance compensation circuit based on the duty cycle,
wherein impedance of a power reception circuit included in the electronic device is compensated based on the adjusted first voltage of the impedance compensation circuit.

12. The method of claim 11, further comprising adjusting a magnitude of the voltage and/or the current of the DC power output from the rectifier circuit by adjusting at least one of a magnitude of the first voltage or the duty cycle.

13. The method of claim 11, further comprising providing power having a specified voltage and a specified current to a battery by adjusting at least one of a magnitude of the first voltage or the duty cycle, while receiving the power wirelessly from the external electronic device.

14. The method of claim 11, wherein the impedance compensation circuit includes a half bridge circuit or a full bridge circuit.

15. The method of claim 14, wherein determining the at least one of the magnitude of the first voltage or the duty cycle comprises:
identifying a first current in the form of an alternating current (AC) supplied from the power reception circuit to the impedance compensation circuit; and
controlling a switching timing of the half bridge circuit or the full bridge circuit to make a phase difference of 90 degrees or −90 degrees between the first current and the first voltage.

16. The method of claim 15, wherein determining the at least one of the magnitude of the first voltage or the duty cycle comprises supplying a voltage having a same magnitude as the first voltage to a capacitor included in the impedance compensation circuit.

17. The method of claim 11, wherein the rectifier circuit does not include a low dropout (LDO) regulator.

18. The method of claim 11, wherein the electronic device further includes a charging circuit supplying power output from the rectifier circuit to the battery, and
wherein the charging circuit does not include a low dropout (LDO) regulator or does not perform a regulation function through control of the duty cycle.

19. The method of claim 18, wherein the charging circuit further includes a switched capacitor (SC) converter converting a voltage of power output from the rectifier circuit.

20. The method of claim 11, further comprising directly supplying power output from the rectifier circuit to the battery.
